(19) United States
(12) Patent Application Publication
(10) Pub. No.: US 2026/0082506 A1
(43) Pub. Date: Mar. 19, 2026

(54) ELECTRONIC APPARATUS

(71) Applicant: Lenovo (Singapore) Pte. Ltd., Singapore (SG)

(72) Inventors: Ryota Watanabe, Kanagawa (JP); Junki Hashiba, Kanagawa (JP); Yudai Tsurumi, Kanagawa (JP); Takateru Adachi, Kanagawa (JP)

(73) Assignee: Lenovo (Singapore) Pte. Ltd., Singapore (SG)

(21) Appl. No.: 19/046,771

(22) Filed: Feb. 6, 2025

(30) Foreign Application Priority Data
Sep. 17, 2024 (JP) 2024-160348

(51) Int. Cl. H05K 7/20; G06F 1/20

(52) U.S. Cl. CPC H05K 7/20145; G06F 1/203

(57) ABSTRACT

An electronic apparatus includes: a chassis having a cover member that forms one surface, and an exhaust port formed in a wall surface intersecting with the one surface; a board that is provided in the chassis, and forms a space, which is in communication with the exhaust port, between the board and an inner surface of the cover member; a heat generating element mounted on the board; a first fan and a second fan that are placed apart with the board located therebetween and have discharge ports in side surfaces facing each other so as to allow air to be discharged into the space; a partition wall that stands between the board and the inner surface of the cover member and extends in one direction toward the exhaust port to partition the first fan and the second fan; a first rectification wall; and a second rectification wall.

### CROSS-REFERENCE TO RELATED APPLICATIONS

This application claims priority to Japanese Patent Application No. 2024-168263 filed on Sep. 17, 2024, the contents of which are hereby incorporated herein by reference in their entirety.

### TECHNICAL FIELD

The present invention relates to an electronic apparatus provided with fans.

### BACKGROUND

An electronic apparatus such as a laptop PC includes heat generating elements such as a CPU. This type of electronic apparatus frequently includes a cooling module with fans or heat sinks. The cooling module is capable of absorbing the heat generated by a heat generating element and dissipating the absorbed heat to the outside (see, for example, Japanese Patent No. 7371170).

According to the configuration disclosed in Japanese U.S. Pat. No. 7,371,170, each of the left and right fans has a pair of discharge ports and is capable of discharging air in two directions. The air leaving one of the discharge ports passes through a heat sink located immediately therebehind and is exhausted to the outside of a chassis. The air leaving the other discharge port flows along the surface of a board placed between the left and right fans and is exhausted to the outside of the chassis while cooling mounted components.

Meanwhile, the air coming out of the other discharge port as described above flows at high speed mainly between the board and the rear surface of a keyboard device. As a result, it has been found that this air may strike the keyboard device or a chassis member, causing the keyboard device or the chassis to vibrate. It has also been found that the air discharged from the left and right fans may collide with each other, leading to the occurrence of vibrations. These vibrations affect the usability of the electronic apparatus. These vibrations affect the usability of electronic devices. On the other hand, the fan air volume could be reduced to suppress the vibrations, but this would lead to deterioration of cooling performance.

### SUMMARY

One or more embodiments of the present invention provide an electronic apparatus capable of suppressing the occurrence of vibrations while ensuring cooling performance.

An electronic apparatus according to an aspect of the present invention includes: a chassis having a cover member that forms one surface, and an exhaust port formed in a wall surface intersecting with the one surface; a board that is provided in the chassis, and forms a space, which is in communication with the exhaust port, between the board and an inner surface of the cover member; a heat generating element mounted on the board; a first fan and a second fan that are placed apart with the board located therebetween and have discharge ports in side surfaces facing each other so as to allow air to be discharged into the space; a partition wall that stands between the board and an inner surface of the cover member and extends in one direction toward the exhaust port to partition the first fan and the second fan; a first rectification wall that stands between the board and the inner surface of the cover member, and extends from one end of the partition wall on the opposite side from the exhaust port toward a discharge port of the first fan; and a second rectification wall that stands between the board and the inner surface of the cover member, and extends from the one end of the partition wall toward a discharge port of the second fan.

According to one or more embodiments of the present invention, the occurrence of vibrations can be suppressed while ensuring cooling performance.

### BRIEF DESCRIPTION OF THE DRAWINGS

FIG. 1 is a schematic plan view of an electronic apparatus according to one or more embodiments observed from above.

FIG. 2 is a plan view schematically illustrating the internal structure of a chassis according to one or more embodiments.

FIG. 3 is a bottom view schematically illustrating the internal structure of the chassis according to one or more embodiments.

FIG. 4 is a side sectional view schematically illustrating the internal structure of the chassis according to one or more embodiments.

FIG. 5 is a side sectional view schematically illustrating the internal structure of the chassis in which a motherboard provided with a bracket and a graphite sheet is installed according to one or more embodiments.

FIG. 6 is a schematic plan view of duct spaces having rectification walls and the surrounding area thereof according to a modified example of one or more embodiments.

FIG. 7 is a schematic plan view of duct spaces having rectification walls and the surrounding area thereof according to another modified example of one or more embodiments.

FIG. 8 is a schematic plan view of duct spaces having rectification walls and the surrounding area thereof according to yet another modified example of one or more embodiments.

### DETAILED DESCRIPTION

The following will describe in detail embodiments of an electronic apparatus according to the present invention with reference to the accompanying drawings.

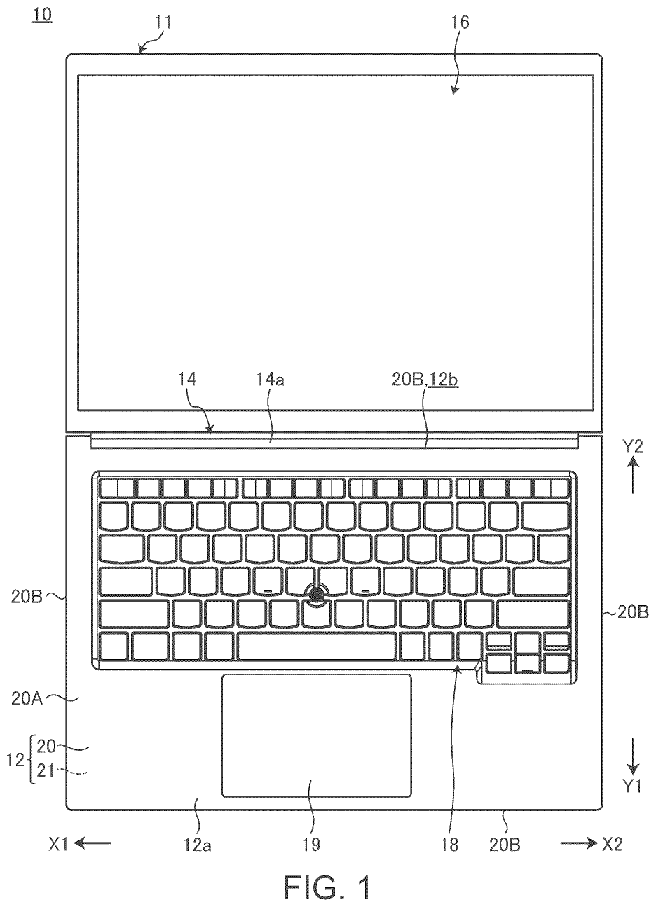

FIG. 1 is a schematic plan view of an electronic apparatus 10 according to one or more embodiments observed from above. As illustrated in FIG. 1, the electronic apparatus 10 of the present embodiment is a clamshell laptop PC. The electronic apparatus 10 has a configuration in which a cover body 11 and a chassis 12 are connected by a hinge 14 so as to be rotatable relative to each other. Although the present embodiment illustrates the electronic apparatus 10 as a laptop PC, the electronic apparatus may alternatively be, for example, a tablet PC, a smartphone, or a portable game machine other than the laptop PC.

The cover body 11 is a thin, flat, box-shaped chassis. The cover body 11 is provided with a display 16. The display 16 is, for example, an organic EL display or a liquid crystal display.

The chassis 12 is a thin, flat box body. A keyboard device 18 and a touchpad 19 are on the upper surface (a surface 12a) of the chassis 12. Hereinafter, the chassis 12 and the components installed therein will be described using the posture of an operator operating the keyboard device 18 as the reference, with the width direction (left and right) of the chassis 12 being referred to as X1 and X2 directions, respectively, the depth direction (front and rear) of the chassis 12 being referred to as Y1 and Y2 directions, respectively, and the thickness direction (top and bottom) of the chassis 12 being referred to as Z1 and Z2 directions, respectively. The X1 and X2 directions may be collectively referred to as the X-direction, and similarly, the Y1 and Y2 directions and the Z1 and Z2 directions may be referred to as the Y-direction and a Z-direction, respectively. These directions are defined for the convenience of explanation, and may of course change, depending on the usage state, the installation attitude, or the like of the electronic apparatus 10.

The chassis 12 is composed of a chassis member 20, which forms the upper surface and the four peripheral side surfaces, and a cover plate 21 forming the lower surface. The chassis member 20 has vertical walls 20B formed on the four peripheral edges of a cover plate 20A, which forms the surface 12a of the chassis 12. Thus, the chassis member 20 has a substantially bathtub shape with an open bottom. The cover plate 21 has a substantially flat plate shape, and serves as a cover that closes the open bottom of the chassis member 20. The chassis member 20 and the cover plate 21 are overlapped in the thickness direction and connected in a mutually detachable manner. The vertical walls 20B may be formed on the cover plate 21. In this case, the chassis member 20 may be composed of only the cover plate 20A.

The hinge 14 is installed in a concave hinge placement groove 12b formed at the rear edge of the chassis 12, and connects the chassis 12 and the cover body 11. The hinge 14 has a structure in which, for example, a hinge shaft serving as a rotating shaft is supported at both ends of a hinge chassis 14a in the longitudinal direction. The hinge 14 of the present embodiment is configured to have a so-called one-bar shape, with the hinge chassis 14a extending along the longitudinal direction of the hinge placement groove 12b. The hinge chassis 14a of the hinge 14 descends diagonally backward while rotating together with the cover body 11. The hinge 14 has a structure that increases the rotation angle of the cover body 11 as described above, which is a so-called drop-down structure. The structure of the hinge 14 may be other than the one described above.

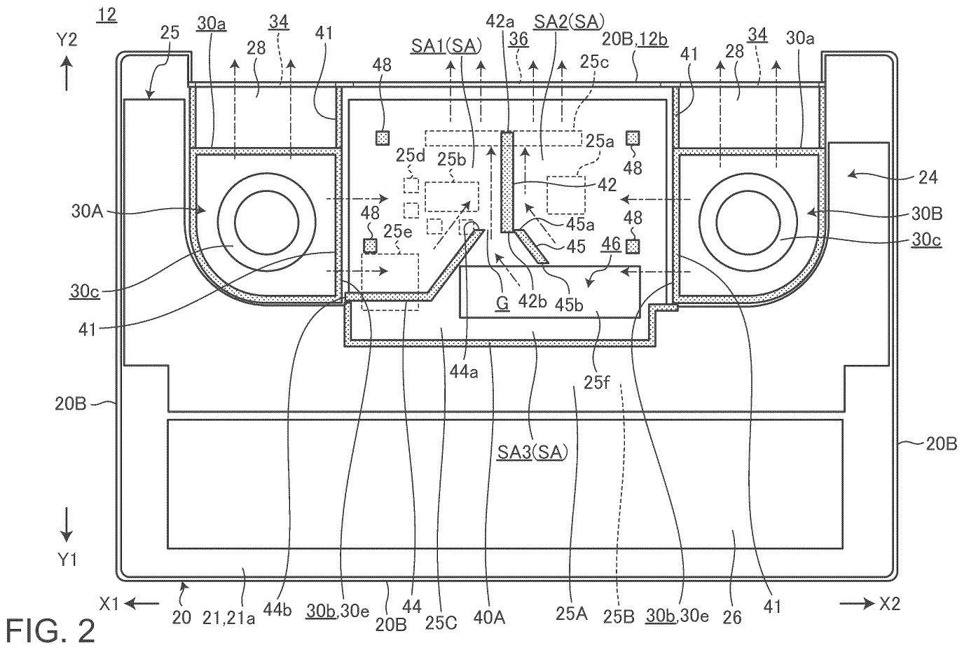

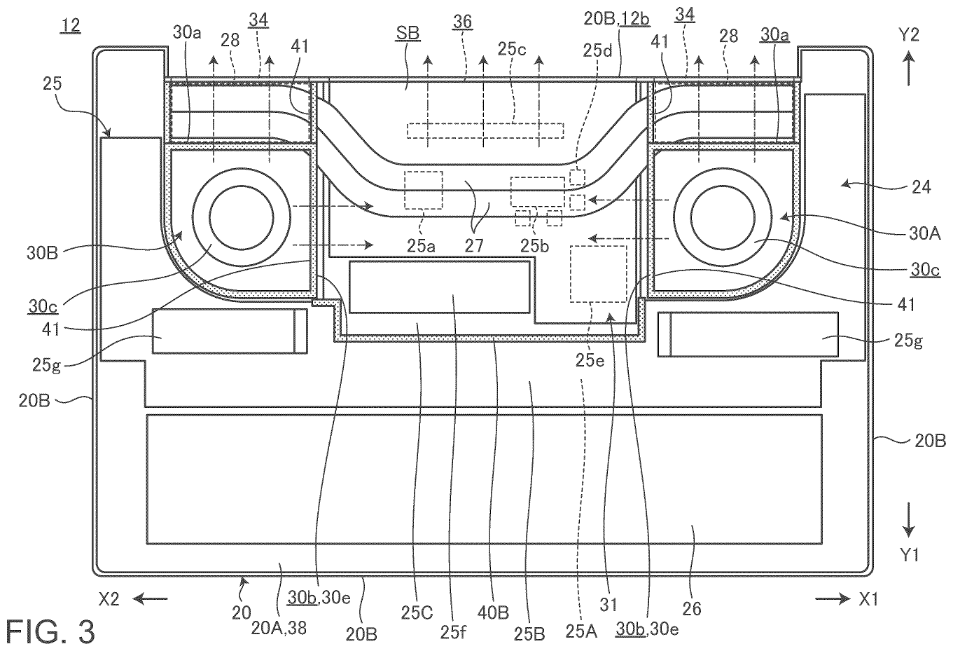

FIG. 2 is a plan view schematically illustrating the internal structure of the chassis 12. FIG. 3 is a bottom view schematically illustrating the internal structure of the chassis 12.

As illustrated in FIG. 2 and FIG. 3, the chassis 12 includes therein a cooling module 24, a motherboard 25, and a battery device 26. Further, various electronic components, mechanical components, and the like are provided inside the chassis 12.

The motherboard (board) 25 is a circuit board serving as the main board of the electronic apparatus 10. The motherboard 25 is placed on a Y2 side in the chassis 12 and extends in an X-direction. The battery device 26 is a rechargeable battery that serves as a power source for the electronic apparatus 10. The battery device 26 is placed on a Y1 side relative to the motherboard 25 and extends in the X-direction.

The motherboard 25 of the present embodiment has a CPU (Central Processing Unit) 25a and a GPU (Graphics Processing Unit) 25b mounted thereon. The CPU 25a is a processing unit that performs calculations related to the main control and processing of the electronic apparatus 10. The GPU 25b is a processing unit that performs calculations necessary for depicting images such as 3D graphics. A power component 25c, GPU memories (VRAM: Video Random Access Memories) 25d, a charge circuit 25e, and the like are mounted around the CPU 25a and the GPU 25b. The power component 25c serves as the power source for the CPU 25a and the GPU 25b. The GPU memories 25d are video memories for the GPU 25b, and, for example, four GPU memories 25d are mounted around the GPU 25b. The charge circuit 25e is a charge control circuit for the battery device 26. Various electronic components such as a memory module 25f, a storage device 25g, and a communication module are further mounted on the motherboard 25. The memory module 25f is, for example, a CAMM (Compression Attached Memory Module) or a DIMM (Dual Inline Memory Module). The storage device 25g is, for example, an SSD (Solid State Drive).

For example, an upper surface (a first surface 25A) of the motherboard 25 serves as the surface of attachment to the chassis member 20, and a lower surface (a second surface 25B) serves as a mounting surface for the CPU 25a and the like.

The CPU 25a and the GPU 25b are heat generating elements that generate the largest amount of heat among the electronic components mounted in the chassis 12. The cooling module 24 can absorb and diffuse the heat generated by the CPU 25a and the GPU 25b, and discharge the heat to the outside of the chassis 12. The cooling module 24 of the present embodiment can also cool the power component 25c, the GPU memories 25d, the charge circuit 25e, the memory module 25f, and the like, which are heat generating elements other than the CPU 25a and the GPU 25b.

As illustrated in FIG. 2 and FIG. 3, the cooling module 24 of the present embodiment includes a set of two heat pipes 27, a pair of heat sinks 28, 28, a pair of fans 30A, 30B, and a heat diffusion member 31.

The heat pipes 27 are pipe-type heat transport devices. The heat pipes 27 are composed of metal pipes thinly and flatly collapsed to form elliptical cross sections, and configured by sealing a working fluid into a sealed space inside. Examples of the working fluid include water, alternative fluorocarbons, acetone, and butane. The heat pipes 27 can be used, for example, in a set of two. The heat pipes 27 partly overlap the CPU 25a and the GPU 25b in the Z-direction, and are connected to the CPU 25a and the GPU 25b. Both ends of the heat pipes 27 are connected to the left and right heat sinks 28. This enables the heat pipes 27 to perform highly efficient transport of the heat, which is generated from the CPU 25a and the GPU 25b, to the left and right heat sinks 28.

In the heat pipes 27, portions near the center in the longitudinal direction, for example, are thermally connected to the CPU 25a and the GPU 25b. The heat diffusion member 31 is interposed between the heat pipes 27 and the CPU 25a and the GPU 25b.

The heat diffusion member 31 is a thin plate formed of a metal having high thermal conductivity such as copper or aluminum. The heat diffusion member 31 of the present embodiment is a copper plate. The heat diffusion member 31 can absorb and diffuse the heat of the CPU 25a and the GPU 25b. The heat diffusion member 31 functions also as a heat transfer member that transmits the heat of the CPU 25a and the GPU 25b to the heat pipes 27. The heat diffusion member 31 can be composed of a vapor chamber.

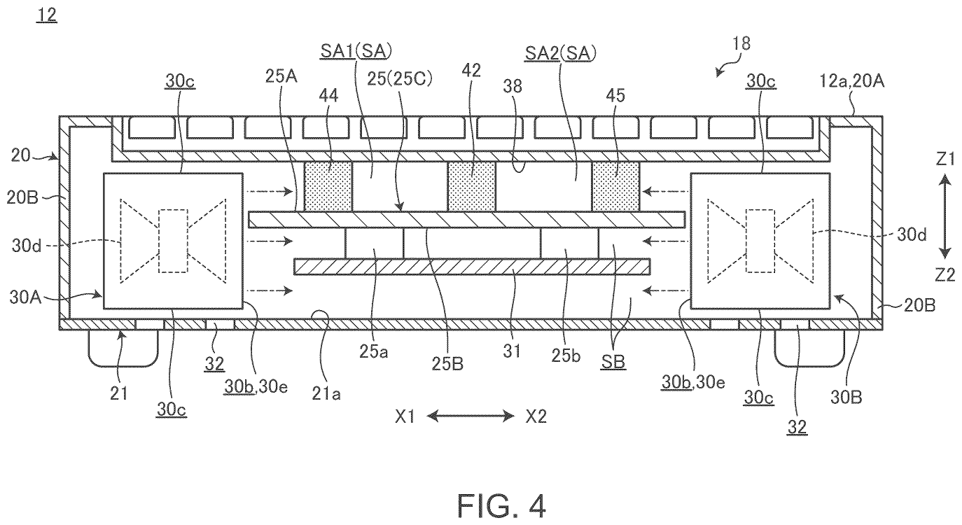

The heat diffusion member 31 extends in a substantially rectangular shape to fill the spaces between the left and right fans 30A, 30B and between the left and right heat sinks 28, 28 as illustrated in FIG. 3. The heat diffusion member 31 covers a part (a part 25C) of the motherboard 25 placed between the left and right fans 30A, 30B, and the CPU 25a and the like mounted on the part 25C from a second surface 25B side (a Z2 side) (refer also to FIG. 4).

The heat sinks 28 are provided at positions close to the edges of the chassis 12 on the X1 side and X2 side. One of the heat sinks 28 is placed opposite a side surface of one fan 30A on the Y2 side (a first discharge port 30a). The other heat sink 28 is placed opposite a side surface of the other fan 30B on the Y2 side (the first discharge port 30a). The heat sink 28 is made of a metal having high thermal conductivity such as aluminum or copper. The heat sinks 28 have a structure in which a plurality of fins made of thin metal plates are arranged at equal intervals in the X-direction. The fins stand in the Z-direction and extend in the Y-direction. The upper and lower end faces (the end faces in the Z-direction) of each fin are integrally supported at thin plate-like portions. A gap, through which air sent from the fans 30A, 30B passes, is formed between adjacent fins. This allows air sent from the first discharge ports 30a of the fans 30A, 30B to pass through heat sinks 28.

As illustrated in FIG. 2, the fans 30A, 30B are provided at positions close to the Y1 side of the left and right heat sinks 28. The fans 30A, 30B have a first discharge port 30a and a second discharge port 30b. The fans 30A, 30B have an intake port 30c in one or both of the upper and lower surfaces thereof. The fans 30A, 30B are centrifugal fans that rotate, by motors, impellers 30d accommodated inside housings (refer to FIG. 4). The fans 30A, 30B discharge, through the discharge ports 30a, 30b, the air drawn in through the intake ports 30c. The intake ports 30c can intake air outside the chassis 12 also through bottom surface vents 32 opened in the bottom surface (the cover plate 21) of the chassis 12 (see FIG. 4).

The first discharge ports 30a discharge air in the Y2 direction. The air sent from the first discharge ports 30a passes through the heat sinks 28. The air that has passed through the heat sinks 28 is discharged to the outside of the chassis 12 through discharge ports 34 formed in vertical walls 20B of the chassis 12 on the Y1 side.

The second discharge ports 30b discharge air in the X1 direction or the X2 direction. The fan 30A placed on the X1 side in FIG. 2 has the second discharge port 30b opened in the side surface thereof on the X2 side. The fan 30B placed on the X2 side in FIG. 2 has the second discharge port 30b opened in the side surface thereof on the X1 side. Thus, the second discharge ports 30b of the left and right fans 30A, 30B oppose each other with the part 25C of the motherboard 25 and the heat diffusion member 31 located therebetween.

The second discharge ports 30b in the Z-direction may be positioned so as to oppose the side edge surfaces of the motherboard 25 and the heat diffusion member 31 (see FIG. 4). This enables the second discharge ports 30b of the fans 30A, 30B to discharge air toward the upper and lower surfaces of the motherboard 25 (the surfaces 25A, 25B) and the upper and lower surfaces of the heat diffusion member 31. The air discharged through the second discharge ports 30b flows along the surfaces 25A, 25B, thus cooling the CPU 25a, the GPU 25b, the memory module 25f, and the like. The air also cools the motherboard 25 and the heat diffusion member 31, which have received the heat from the heat generating elements, and is exhausted to the outside of the chassis 12 through an exhaust port 36 formed in the vertical wall 20B of the chassis 12 on the Y1 side. The exhaust port 36 is positioned between the left and right exhaust ports 34, 34. The exhaust port 36 is in communication with upper and lower duct spaces SA, SB, through which the air discharged from the second discharge ports 3b of the left and right fans 30A, 30B flows.

A description will now be given of a configuration example of the duct spaces SA, SB. FIG. 4 is a side sectional view schematically illustrating the internal structure of the chassis 12. FIG. 4 omits illustrating the heat pipes 27 and the like.

As illustrated in FIG. 2 and FIG. 4, the duct space SA on the upper side is a flat space that is low in the Z-direction, and is formed between the first surface 25A of the part 25C and an inner surface 38 of the cover plate 20A. In the case of the present embodiment, there is the keyboard device 18 above the part 25C, meaning that the inner surface 38 is also the bottom surface of the keyboard device 18. Both edges of the duct space SA on the X side can be formed by the left and right fans 30A, 30B and heat sinks 28, 28. The edge of the duct space SA on the Y2 side can be formed by the vertical wall 20B on the Y2 side, which has the exhaust port 36. The edge of the duct space SA on the Y1 side can be formed by an airtight wall 40A.

The airtight wall 40A is, for example, a long and narrow member formed of sponge or rubber in a strip shape. The airtight wall 40A is not required to be capable of completely blocking the passage of air, but is required to have at least a certain degree of ventilation resistance to be capable of regulating the direction of air flow. The airtight wall 40A stands between the first surface 25A of the motherboard 25 and the inner surface 38 of the keyboard device 18. The airtight wall 40A can be attached to the motherboard 25 or the keyboard device 18 with, for example, double-sided adhesive tape. The airtight wall 40A extends in such a manner as to connect side surfaces 30e, 30e in which the second discharge ports 30b of the left and right fans 30A, 30B are formed. Both ends of the airtight wall 40A are in contact with or close to the ends of the side surfaces 30e on the Y1 side. Both ends of the airtight wall 40A are located in positions that do not block the second discharge ports 30b. As will be described later, the duct space SA of the present embodiment accommodates rectification walls 44, 45, so that the airtight wall 40A can be omitted (see FIG. 7).

Symbol 41 in FIG. 2 and FIG. 3 denotes an airtight wall formed of a material that is the same as or similar to that of the airtight wall 40A. The airtight walls 41 stand between the outer edges of the housings of the fans 30A, 30B and the outer edges of the heat sinks 28 and the inner surface 38 or an inner surface 21a of the cover plate 21. An airtight wall 40B can be attached to the motherboard 25 or the cover plate 21 with, for example, double-sided adhesive tape. The airtight wall 41 airtightly seals the edges of the duct spaces SA and SB on the X side, and also airtightly seals mainly the peripheries of the intake ports 30c of the fans 30A and 30B.

As illustrated in FIG. 2 and FIG. 4, the duct space SA accommodates a partition wall 42 and the pair of the rectification walls 44, 45. The partition wall 42 and the rectification walls 44, 45 can be formed of a material that is the same as or similar to that of the airtight wall 40A described above. The partition wall 42 and the rectification walls 44, 45 of the present embodiment are made of sponge that has a certain degree of ventilation resistance to be capable of regulating the direction of air flow. The partition wall 42 and the rectification walls 44, 45 can be attached to the motherboard 25, the cover plate 20A or the keyboard device 18 or the like with, for example, double-sided adhesive tape.

The partition wall 42 stands between the first surface 25A and the inner surface 38. The partition wall 42 extends in a bar shape in the Y-direction between the left and right fans 30A, 30B toward the exhaust port 36. This enables the partition wall 42 to divide the duct space SA into a first space SA1, to which the second discharge port 30b of one fan 30A faces, and a second space SA2, to which the second discharge port 30b of the other fan 30B faces. The partition wall 42 does not have to completely partition the area in the duct space SA in the Y-direction. The partition wall 42 having the example configuration illustrated in FIG. 2 partitions only a part of the area of the duct space SA in the Y-direction. To be specific, an end 42a of the partition wall 42 on the Y2 side is located apart from the vertical wall 20B with the exhaust port 36 formed therein. The end 42a may alternatively be located close to the exhaust port 36. An end 42b on the Y1 side is located apart from the airtight wall 40A.

The partition wall 42 may have a length in the Y-direction that makes it possible to prevent direct collision between the air discharged from the discharge ports 30b of the fans 30A, 30B. In one or more embodiments, therefore, the end 42a of the partition wall 42 on the Y2 side is located closer to the Y2 side relative to the second discharge ports 30b of the fans 30A, 30B. The end 42a is located, for example, at a position that overlaps with the left and right heat sinks 28 in the X-direction. Meanwhile, in the case of the present embodiment, the end 42b of the partition wall 42 on the Y1 side is located at the position that overlaps with the second discharge ports 30b of the fans 30A, 30B in the X-direction. The Y1 side of the partition wall 42 is complemented by the rectification walls 44, 45. This prevents the air discharged from the discharge ports 30b from directly colliding with each other.

The rectification walls 44, 45 stand between the first surface 25A and the inner surface 38. The rectification walls 44, 45 are located between the partition wall 42 and the airtight wall 40A in the Y-direction. The rectification walls 44, 45 form a bypass space (bypass path) SA3 between themselves and the airtight wall 40A. The bypass space SA3 is a space in which spaces SA1, SA2 are partitioned by the rectification walls 44, 45.

The rectification wall 44 on the X1 side extends in a substantially boomerang shape from the end 42b of the partition wall 42 toward the second discharge port 30b of the fan 30A on the X1 side. The rectification wall 44 causes the air discharged from the second discharge port 30b of the fan 30A to flow along the partition wall 42 to the exhaust port 36. The rectification wall 44 extends in the Y1 direction from an end 44a on the partition wall 42 side to an end 44b on the opposite side so as to gradually incline toward the X1 side. Thereafter, the rectification wall 44 bends and extends in the X1 direction toward the second discharge port 30b. In the case of the present embodiment, the end 44a is placed with a gap G provided between the end 44a and the end 42b of the partition wall 42. The end 44b is close to the end of the second discharge port 30b on the Y1 side in the width direction (the Y-direction).

The rectification wall 45 on the X2 side extends in a bar shape from the end 42b of the partition wall 42 to the second discharge port 30b of the fan 30B on the X2 side. The rectification wall 45 causes the air discharged from the second discharge port 30b of the fan 30B to flow along the partition wall 42 to the exhaust port 36. The rectification wall 45 extends in the Y1 direction from an end 45a adjacent to the partition wall 42 to an end 45b on the opposite side in such a manner as to gradually incline toward the X2 side. In the case of the present embodiment, the end 45a is in contact with or close to the end 42b of the partition wall 42. In this case, the ends 44a and 45a of the rectification walls 44 and 45 can be positioned closer to the Y2 side than the end 42b of the partition wall 42. In other words, the end 42b and the end 44a, 45a can be positioned so as to overlap with each other in the X-direction.

The end 45b of the rectification wall 45 is positioned significantly apart from the second discharge port 30b of the fan 30B. In other words, in the case of the present embodiment, the rectification wall 45 on the X2 side is shorter than the rectification wall 44 on the X1 side. The end 45b of the rectification wall 45 forms a gap (an introduction port 46) between the second discharge port 30b of the fan 30B and the airtight wall 40A. This means that the rectification wall 45 has one end thereof (the end 45b) on the far side from the exhaust port 36 positioned closer to the exhaust port 36 than one end (the end of the discharge port 30b on the Y1 side) on the far side from the exhaust port 36 of the discharge port 30b of the fan 30B. The introduction port 46 serves as an entrance to introduce air discharged from the second discharge port 30b of the fan 30B into the bypass space SA3. The exit of the bypass space SA3 is the gap G. The introduction port 46 may be formed by positioning one end (the end 44b) of the rectification wall 44, which one end is farther from the exhaust port 36, closer to the exhaust port 36 than one end (the end of the discharge port 30b on the Y1 side) of the discharge port 30b of the fan 30A, which one end is farther from the exhaust port 36. The introduction port 46 may be formed in both the rectification walls 44 and 45.

The memory module 25f is, for example, a CAMM, as described above. Therefore, the memory module 25f has components, such as brackets, thereof exposed on the first surface 25A, which is the back side of the mounting surface. Hence, the rectification wall 45 is formed to be shorter than the rectification wall 44, partly for the purpose of avoiding the memory module 25f. At least a part of the memory module 25f vertically overlaps with the duct space SA in a plan view.

Symbol 48 in FIG. 2 denotes a spacer. The spacers 48 are formed, for example, in a rectangular shape, and four spacers 48 are placed substantially evenly in the duct space SA. The spacers 48 can be formed of a material that is the same as or similar to that of the airtight wall 40A described above. The spacers 48 stand between the first surface 25A and the inner surface 38, and serve as pillars that support the duct space SA. The shape and placement of the spacers 48 can be changed as appropriate. The spacers 48 may be omitted.

As illustrated in FIG. 3 and FIG. 4, a lower duct space SB is a flat space that is low in the Z-direction, and is formed between the second surface 25B of the part 25C and the inner surface 21a of the cover plate 21. Both edges of the duct space SB on the X side can be formed by the left and right fans 30A, 30B and heat sinks 28, 28. The edge of the duct space SB on the Y2 side can be formed by the Y2-side vertical wall 20B having the exhaust port 36. The edge of the duct space SB on the Y1 side can be formed by the airtight wall 40B.

The airtight wall 40B can be formed of a material that is the same as or similar to that of the airtight wall 40A. The airtight wall 40B stands between the second surface 25B of the motherboard 25 and the inner surface 21a of the cover plate 21. The airtight wall 40B may be provided only between the heat diffusion member 31 and the inner surface 21a. The shape of the airtight wall 40B in the longitudinal direction can be formed to be substantially the same as that of the airtight wall 40A in a plan view.

A description will now be given of the cooling operation and the action and effect of the electronic apparatus 10.

In the electronic apparatus 10, the heat generated from the CPU 25a and the GPU 25b is transmitted to the heat pipes 27 and efficiently transported to the heat sinks 28. The heat transported to the heat sinks 28 is discharged to the outside of the chassis 12 by the air flowing from the first discharge ports 30a of the fans 30A, 30B to the exhaust port 34. The arrows indicated by the chain lines in FIG. 2 to FIG. 8 schematically show the flows of the air discharged from the fans 30A, 30B.

The heat generated from the CPU 25a and the GPU 25b is partly transmitted also to the motherboard 25. The heat generated from other heat generating elements, such as the power component 25c, the GPU memories 25d, the charge circuit 25e, and the memory module 25f, is also transmitted to the motherboard 25. The heat is transferred also to the first surface 25A, which is the rear surface of the mounting surface (the second surface 25B) of the motherboard 25. The heat transmitted to the motherboard 25 is cooled by the air that flows from the second discharge ports 30b of the fans 30A, 30B to the duct spaces SA, SB.

In this case, the duct space SA is divided into the left and right spaces SA1, SA2 by the partition wall 42. Consequently, the air discharged into the first space SA1 from the second discharge port 30b of the fan 30A smoothly flows along the partition wall 42 by the rectification action of the rectification wall 44, and is directed toward the exhaust port 36. The air flowing through the first space SA1 cools the heat transmitted from the GPU 25b, the GPU memories 25d, and the charge circuit 25e, in particular, to the motherboard 25, and is discharged through the exhaust port 36.

The air discharged into the second space SA2 from the second discharge port 30b of the fan 30B smoothly flows along the partition wall 42 by the rectification action of the rectification wall 45, and is directed toward the exhaust port 36. The air flowing into the second space SA2 cools the heat transmitted from the CPU 25a and the memory module 25f, in particular, to the motherboard 25, and is discharged through the exhaust port 36. A part of the air discharged into the second space SA2 from the fan 30B passes through the introduction port 46, and flows into the bypass space SA3. The air flowing into the bypass space SA3 passes through the gap G into the first space SA1, and is directed toward the exhaust port 36. The air flowing into the bypass space SA3 cools the memory module 25f, in particular, and is discharged through the exhaust port 36.

As described above, the electronic apparatus 10 of the present embodiment includes the chassis 12 having the cover member (the cover plate 20A) that forms the surface 12a. The chassis 12 has the exhaust port 36 in the vertical wall 20B forming the wall surface that intersects with the surface 12a. The electronic apparatus 10 includes the motherboard 25 that has the space (the duct space SA), which is in communication with the exhaust port 36, between the cover plate 20A or the inner surface 38 of the keyboard device 18. The chassis 12 houses the fans 30A, 30B, which are placed with the motherboard 25 (the part 25C) located therebetween, and have the second discharge ports 30b in the side surfaces 30e that face each other. The chassis 12 is further provided therein with the partition wall 42, which extends in one direction toward the exhaust port 36 so as to partition the fans 30A, 30B, and the rectification walls 44, 45 extending from the end 42b of the partition wall 42 to the second discharge ports 30b of the fans 30A, 30B.

Thus, in the electronic apparatus 10, the air discharged from the second discharge ports 30b of the fans 30A, 30B into the duct space SA is rectified so as to flow along the partition wall 42 from the rectification walls 44, 45, and to be smoothly discharged to the exhaust port 36. This enables the electronic apparatus 10 to suppress a situation in which the flow of air moving at high speed through the duct space SA is disturbed and collides with the inner surface 38 in a striking manner, causing the chassis 12 to vibrate due to the kinetic energy of the air. At the same time, the partition wall 42 and the rectification walls 44, 45 prevent direct collision between the air discharged from the left and right second discharge ports 30b facing each other. This enables the electronic apparatus 10 to suppress the occurrence of vibrations caused by the collision between the air discharged from the fans 30A, 30B. Thus, the electronic apparatus 10 can suppress the occurrence of vibrations without reducing the air volume of the fans 30A, 30B. Thus, the electronic apparatus 10 can improve usability while ensuring the cooling performance.

In this case, the partition wall 42 and the rectification walls 44, 45 can overlap with each other in the X-direction in which the second discharge ports 30b of the fans 30A, 30B face each other. This allows the fans 30A, 30B to be securely partitioned from each other by the partition wall 42 and the rectification walls 44, 45. Thus, the electronic apparatus 10 can further suppress the occurrence of vibrations caused by collisions between the air discharged from the fans 30A, 30B.

In one or more embodiments, the partition wall 42 is not in contact with the airtight wall 40A. This is because, if the end 44b of the partition wall 42 were to extend to the airtight wall 40A, a dead space where air remains might be generated at the corner between the partition wall 42 and the airtight wall 40A, thus leading to deterioration of the cooling performance in this area.

Meanwhile, the keyboard device 18 is a part that an operator touches with his or her fingertips. Hence, suppressing the vibrations of the keyboard device 18 contributes to a significant improvement in usability. For this reason, the partition wall 42 and the rectification walls 44, 45 may be installed in the duct space SA formed between the keyboard device 18 and the motherboard 25.

The following will describe the results of a comparative experiment on vibration intensity between the configuration of the embodiment in which the partition wall 42 and the rectification walls 44, 45 are provided in the duct space SA as illustrated in FIG. 2 and the configuration of a comparative example in which the partition wall 42 and the rectification walls 44, 45 are not provided in the duct space SA. In the experiment, the vibration intensity (dB) on the surface of a key top of the keyboard device 18 was measured for the embodiment and the comparative example. The experiment results indicated that the vibration intensity in the embodiment was 69.1 (dB), and the vibration intensity in the comparative example was 73.2 (dB). This shows that the embodiment can reduce the vibration generated by the discharge air of the fans 30A, 30B in comparison with the comparative example.

The electronic apparatus 10 can have the gap G between the end 42b of the partition wall 42 and the end 44a of the rectification wall 44. This enables the electronic apparatus 10 to cause also the air flowing in to the Y2 side of the rectification walls 44, 45 to flow to the exhaust port 36 through the gap G. As a result, the cooling performance of the electronic apparatus 10 is further improved.

The electronic apparatus 10 can be provided with the airtight wall 40A, which extends so as to connect the mutually facing side surfaces 30e, 30e of the fans 30A, 30B. The duct space SA can have, between the airtight wall 40A and the rectification walls 44, 45, the bypass space SA3 into which the air discharged from the second discharge port 30b of the fan 30B is introduced. This makes it possible for the electronic apparatus 10 to efficiently cool the heat from a heat generating element (e.g., the memory module 25f), which is positioned in the bypass space SA3, by the air from the second discharge port 30b. The air introduced into the bypass space SA3 smoothly flows to the exhaust port 36 through the gap G.

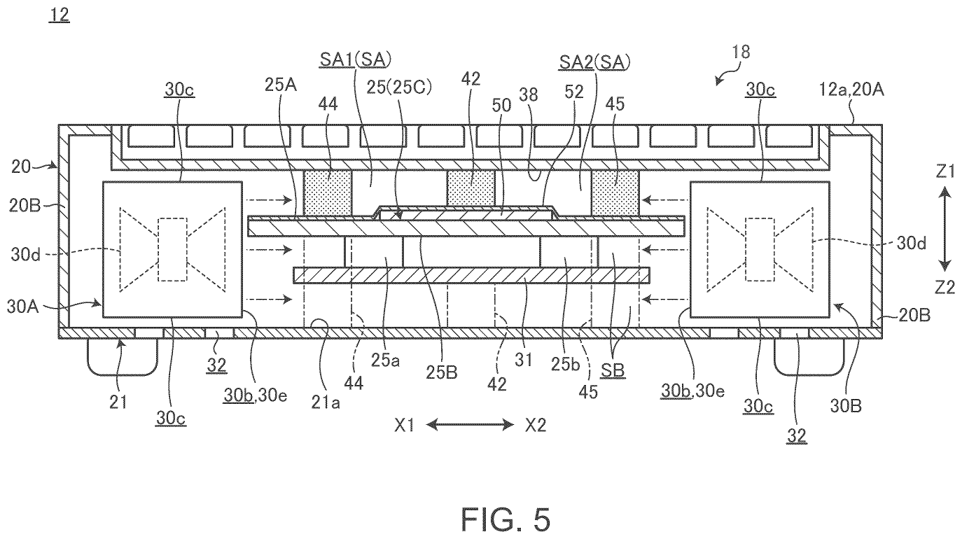

FIG. 5 is a side sectional view schematically illustrating the internal structure of the chassis 12, in which the motherboard 25 provided with a bracket 50 and a graphite sheet 52 is installed.

As illustrated in FIG. 5, the bracket 50 can be provided on the first surface 25A of the motherboard 25. The bracket 50 is a sheet metal component formed in a lattice or mesh pattern in a plan view, and is made of, for example, SUS. The bracket 50 is a reinforcing component that suppresses warping of the motherboard 25 and prevents the mounted components from falling off. In this case, the partition wall 42 and the rectification walls 44, 45 may be installed on the bracket 50 or at positions that avoid the bracket 50. In the configuration example illustrated in FIG. 5, the partition wall 42 is placed over the entire length thereof on the bracket 50. Consequently, the partition wall 42 can be formed over the entire length thereof using, for example, a single sponge, eliminating the need for using sponges of different thicknesses thereby to reduce the number of components. Similarly, the rectification walls 44, 45 in the configuration example illustrated in FIG. 5 are each placed over the entire length thereof in a position where the bracket 50 is absent. This also reduces the number of components for the rectification walls 44, 45.

As illustrated in FIG. 5, the graphite sheet 52 can be provided on the first surface 25A of the motherboard 25. The graphite sheet 52 can be laid so as to cover most of the part 25C. The graphite sheet 52 is a heat dissipation member that promotes heat dissipation from the motherboard 25. In this case, the partition wall 42 and the rectification walls 44, 45 should be installed on the graphite sheet 52.

As indicated by the two-dot chain lines in FIG. 5, the partition wall 42 and the rectification walls 44, 45 can be installed in the duct space SB. In this case, the partition wall 42 and the rectification walls 44, 45 can stand between the second surface 25B of the motherboard 25 and the inner surface 21a of the cover plate 21. The partition wall 42 and the rectification walls 44, 45 may be configured to stand between the heat diffusion member 31 and the inner surface 21a of the cover plate 21, as with the partition wall 42 indicated by the two-dot chain lines in FIG. 5. As described above, in the electronic apparatus 10, the partition wall 42 and the rectification walls 44, 45 can be provided in one or both of the duct spaces SA, SB.

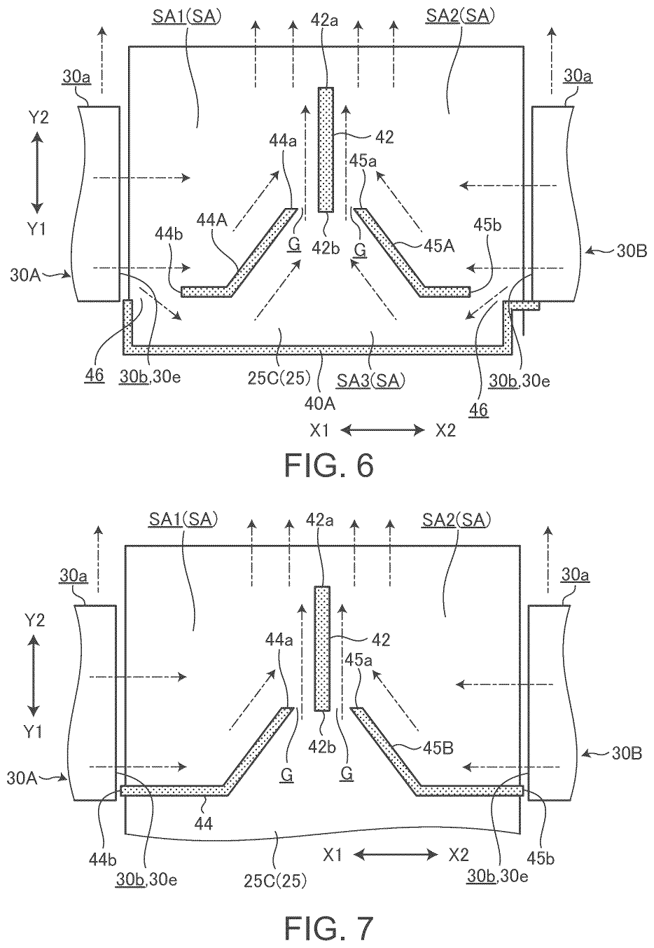

FIG. 6 is a schematic plan view of duct spaces SA having rectification walls 44A, 45A and the surrounding area thereof according to a modified example.

The entire length of the rectification wall 44A illustrated in FIG. 6 is shorter than that of the rectification wall 44 illustrated in FIG. 2. In the rectification wall 44A, the bar-shaped portion thereof in the X-direction from the bent portion between the ends 44a, 44b toward the end 44b is shorter than that of the rectification wall 44. The rectification wall 45A illustrated in FIG. 6 has a shorter entire length than the rectification wall 45 illustrated in FIG. 2, and is formed in a shape that is substantially symmetrical to the rectification wall 44A. The ends 44b, 45b of the rectification walls 44A, 45A are located away from the side surfaces 30e of the fans 30A, 30B, respectively. Introduction ports 46 for the bypass space SA3 are formed between the ends 44b, 45b of the rectification walls 44A, 45A and the airtight wall 40A. The end 45a of the rectification wall 45A can be placed with the gap G provided between the end 45a and the end 42b of the partition wall 42. At least one of the ends 44a, 45a of the rectification walls 44A, 45B need to have the gap G between the one and the partition wall 42, and the other may be in contact with the partition wall 42.

FIG. 7 is a schematic plan view of the duct spaces SA having a rectification wall 45B and the surrounding area thereof according to another modified example.

The entire length of the rectification wall 45B illustrated in FIG. 7 is greater than that of the rectification wall 45 illustrated in FIG. 2. The rectification wall 45B is formed to be substantially symmetrical to the rectification wall 44 illustrated in FIG. 2 and FIG. 7. An end 45b of the rectification wall 45B is positioned close to a side surface 30e of a fan 30B. The configuration example illustrated in FIG. 7 is suited to, for example, a configuration without the airtight wall 40A. In other words, according to the configuration example illustrated in FIG. 7, the air flowing to the Y1 side of the rectification walls 44, 45B mainly through the small gaps between the rectification walls 44, 45B and the side surfaces 30e can be discharged to the exhaust port 36 through the gaps G, thus ensuring the cooling performance. The gaps G between the rectification walls 44, 45B and the partition wall 42 can also allow heat inside the chassis 12 on the Y2 side relative to the rectification walls 44, 45B to pass toward the exhaust port 36.

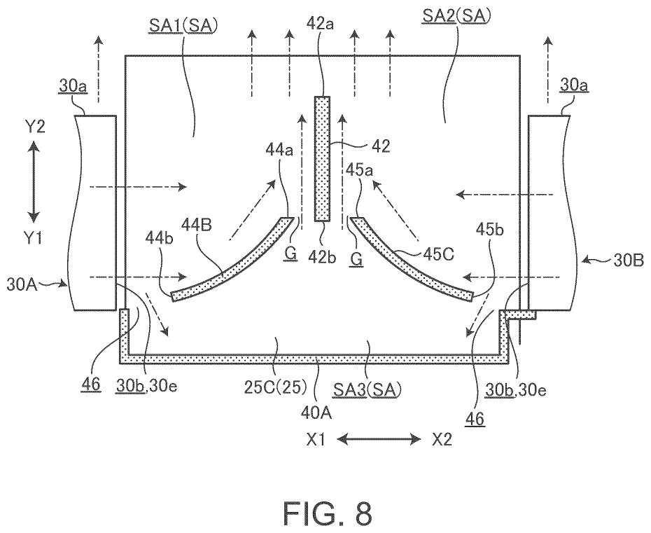

FIG. 8 is a schematic plan view of duct spaces SA having rectification walls 44B, 45C and the surrounding area thereof according to yet another modified example.

The rectification walls 44B, 45C illustrated in FIG. 8 are different from the rectification walls 44A, 45A illustrated in FIG. 6 in that the rectification walls 44B, 45C do not have bent shapes with bent portions in the middle, but are curved in an arc shape as a whole. The rectification walls 44B, 45C further smoothen the flow of air from the second discharge ports 30b toward the exhaust port 36 in comparison with the rectification walls 44A, 45A illustrated in FIG. 6. The curved shapes of the rectification walls 44B, 45C can also be applied to the rectification walls 44, 45 illustrated in FIG. 2.

It is needless to say that the present invention is not limited to the embodiments described above, and modifications can be freely made within the scope not departing from the gist of the present invention.

### DESCRIPTION OF SYMBOLS

10 electronic apparatus
11 cover body
12 chassis
18 keyboard device
24 cooling module
25 motherboard
25a CPU
25b GPU
25f memory module
30A, 30B fan
30a first discharge port
30b second discharge port
34, 36 exhaust port
40A, 40B, 41 airtight wall
42 partition wall
44, 44A, 44B, 45, 45A, 45B, 45C rectification wall

What is claimed is:

1. An electronic apparatus comprising:
a chassis having a cover member that forms one surface, and an exhaust port formed in a wall surface intersecting with the one surface;
a board that is provided in the chassis, and forms a space, which is in communication with the exhaust port, between the board and an inner surface of the cover member;
a heat generating element mounted on the board;
a first fan and a second fan that are placed apart with the board located therebetween and have discharge ports in side surfaces facing each other so as to allow air to be discharged into the space;
a partition wall that stands between the board and the inner surface of the cover member and extends in one direction toward the exhaust port to partition the first fan and the second fan;
a first rectification wall that stands between the board and the inner surface of the cover member, and extends from one end of the partition wall on the opposite side from the exhaust port toward a discharge port of the first fan; and
a second rectification wall that stands between the board and the inner surface of the cover member, and extends from the one end of the partition wall toward a discharge port of the second fan.

2. The electronic apparatus according to claim 1,
wherein a gap is provided between the one end of the partition wall and at least one of the first rectification wall and the second rectification wall.

3. The electronic apparatus according to claim 2, including:
an airtight wall that stands between the board and an inner surface of the cover member, and extends so as to connect one side surface of the first fan and one side surface of the second fan, thereby forming a duct space, which accommodates the partition wall, the first rectification wall, and the second rectification wall, between the airtight wall and the exhaust port,
wherein a bypass space, into which air discharged from the discharge port of at least one of the first fan and the second fan is introduced and which causes the introduced air to flow through the gap to the exhaust port, is formed between the airtight wall and the first rectification wall and the second rectification wall.

4. The electronic apparatus according to claim 3,
wherein, in a plan view of the board, the heat generating element is placed between the first rectification wall and the second rectification wall and the exhaust port, and another heat generating element that is different from the heat generating element is placed in the bypass space.

5. The electronic apparatus according to claim 2,
wherein at least one of the first rectification wall and the second rectification wall has one end thereof on a far side from the exhaust port being positioned closer to the exhaust port than one end of the discharge port on the far side from the exhaust port.

6. The electronic apparatus according to claim 1, including:
a keyboard device on one surface of the chassis,
wherein the partition wall, the first rectification wall and the second rectification wall stand between the board and the keyboard device.

7. The electronic apparatus according to claim 1,
wherein the partition wall and the first rectification wall and the second rectification wall overlap with each other with respect to a direction in which the discharge ports of the first fan and the second fan oppose each other.
